(19) United States
(12) Patent Application Publication
(10) Pub. No.: US 2013/0056260 A1
(43) Pub. Date: Mar. 7, 2013

(54) TERMINAL CONNECTOR HEAD

(71) Applicants: Allan F. Heisler, II, Huntertown, IN (US); Kevin J. Slane, Fort Wayne, IN (US)

(72) Inventors: Allan F. Heisler, II, Huntertown, IN (US); Kevin J. Slane, Fort Wayne, IN (US)

(73) Assignee: PYROMATION, INC., FORT WAYNE, IN (US)

(21) Appl. No.: 13/223,460

(22) Filed: Sep. 1, 2011

(51) Int. Cl. H05K 5/00

(52) U.S. Cl. 174/520; 174/50

(57) ABSTRACT

A terminal connector head with a housing and a cover for removably mounting to the housing. In one embodiment, the housing has holes formed in an inner surface for alternatively receiving either a first type of terminal block or a second type of terminal block. The first terminal block and the second terminal block are configured to be mounted in the housing by one or more attachment members which are received in a plurality of the holes.

### TECHNICAL FIELD

This invention relates generally to terminal connector heads and more particularly to terminal connector heads used with temperature sensors.

### BACKGROUND

Terminal connector heads are frequently used with temperature sensors. A temperature sensor typically comprises a temperature sensing element, such as a thermocouple, encased in a protection tube. The sensing element provides or varies an electrical signal which is indicative of temperature. This electrical signal is transmitted to a process instrument which translates it into usable information. Such a process instrument might be a digital readout or an analog/digital converter.

Terminal connector heads must usually be used with temperature sensors because the sensing element typically has short lead wires. Consequently, these lead wires must be connected to other wires which are then run back to the process instrument. This interconnection is done in a terminal connector head and by the terminals and terminal strips in the terminal connector head.

The terminal connector head must be designed to withstand the environmental conditions which exist where it is mounted. Since it must typically be mounted very close to the process which is being sensed by the sensing element, these environmental conditions can be severe. For example, if a temperature sensor is used to sense high temperatures such as exist in furnaces, the terminal connector head can be exposed to very high temperatures.

### SUMMARY

According to one aspect, the present invention provides a terminal connector head with a housing and a cover for removably mounting to the housing. The housing has holes formed in an inner surface for alternatively receiving either a first type of terminal block or a second type of terminal block. The first terminal block and the second terminal block are configured to be mounted in the housing by one or more attachment members which are received in a plurality of the holes.

According to another aspect, the invention provides a terminal connector head with a housing and a cover for removably mounting to the housing. The housing has an annular threaded perimeter and the cover has an annular threaded perimeter which threadably mates with the housing's annular threaded perimeter. The annular threaded perimeter of the housing and the annular threaded perimeter of the cover are configured for the cover to screw onto the housing with a rotation less than approximately 180 degrees. The housing has a threaded process opening and a threaded conduit opening.

Additional features and advantages of the invention will become apparent to those skilled in the art upon consideration of the following detailed description of the illustrated embodiment exemplifying the best mode of carrying out the invention as presently perceived. It is intended that all such additional features and advantages be included within this description and be within the scope of the invention.

### BRIEF DESCRIPTION OF THE DRAWINGS

The present disclosure will be described hereafter with reference to the attached drawings which are given as non-limiting examples only, in which:

FIG. 1 is a front perspective view of an example terminal connector head according to one embodiment of the present invention;

FIG. 2 is a right side view of the example terminal connector head shown in FIG. 1 without the chain;

FIG. 3 is a left side view of the example terminal connector head shown in FIG. 1 without the chain;

FIG. 4 is a front perspective view of the housing of the example terminal connector head shown in FIG. 1 with the cover removed and without a terminal block;

FIG. 5 is a front perspective view of the housing of the example terminal connector head shown in FIG. 1 with the cover removed and with a first type of terminal block installed;

FIG. 6 is a front perspective view of the housing of the example terminal connector head shown in FIG. 1 with the cover removed and with a second type of terminal block installed;

FIG. 7 is a left side cross sectional perspective view of the example terminal connector head shown in FIG. 1 with the first type of terminal block installed;

FIG. 8 is a rear perspective view of the terminal connector head shown in FIG. 7;

FIG. 9 is a left side cross sectional view of the example terminal connector head shown in FIG. 7 with the cover unscrewed; and

FIG. 10 is a left side cross sectional view of the example terminal connector head shown in FIG. 9 with the cover fully screwed.

Corresponding reference characters indicate corresponding parts throughout the several views. The components in the figures are not necessarily to scale, emphasis instead being placed upon illustrating the principals of the invention. The exemplification set out herein illustrates embodiments of the invention, and such exemplification is not to be construed as limiting the scope of the invention in any manner.

### DETAILED DESCRIPTION OF THE DRAWINGS

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the disclosure.

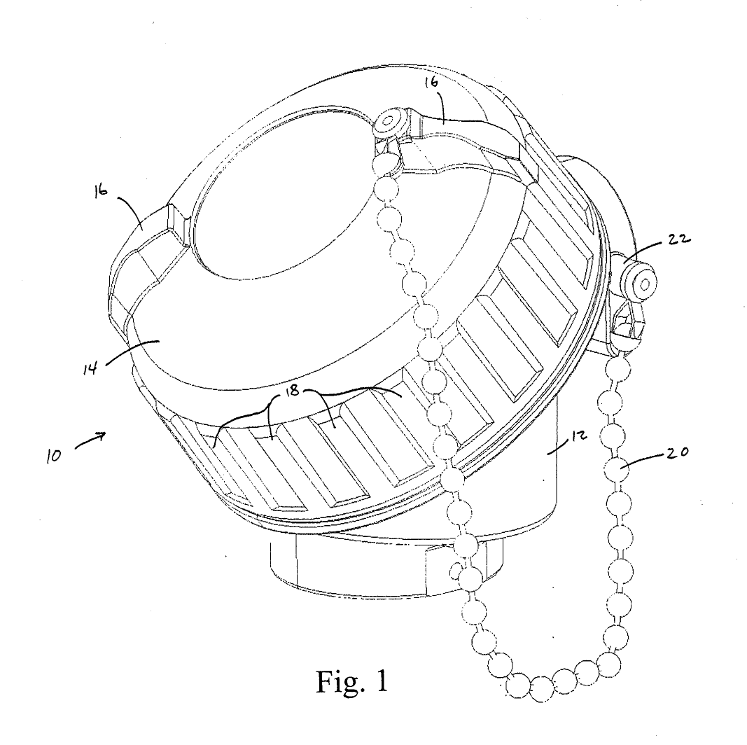

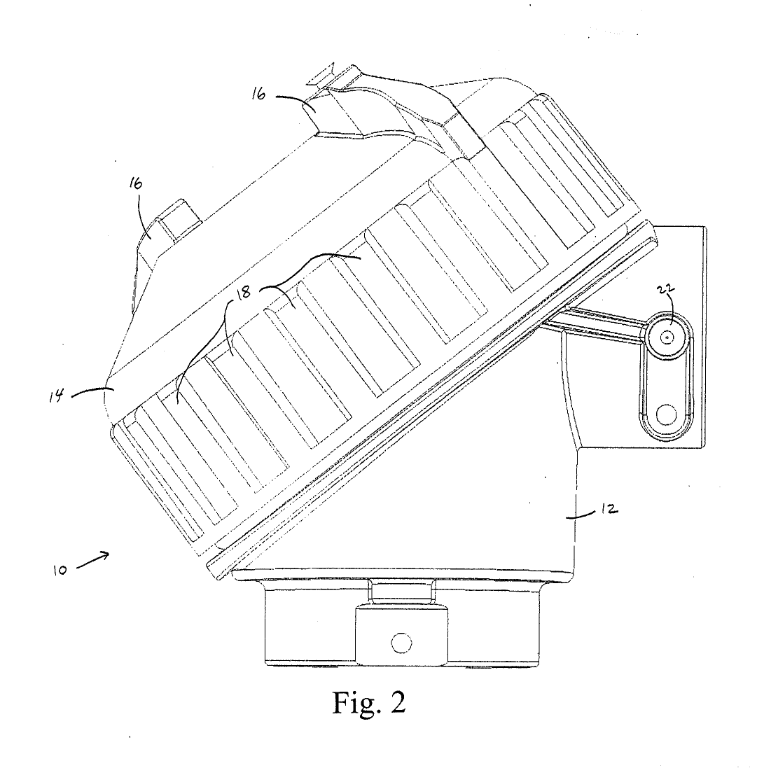

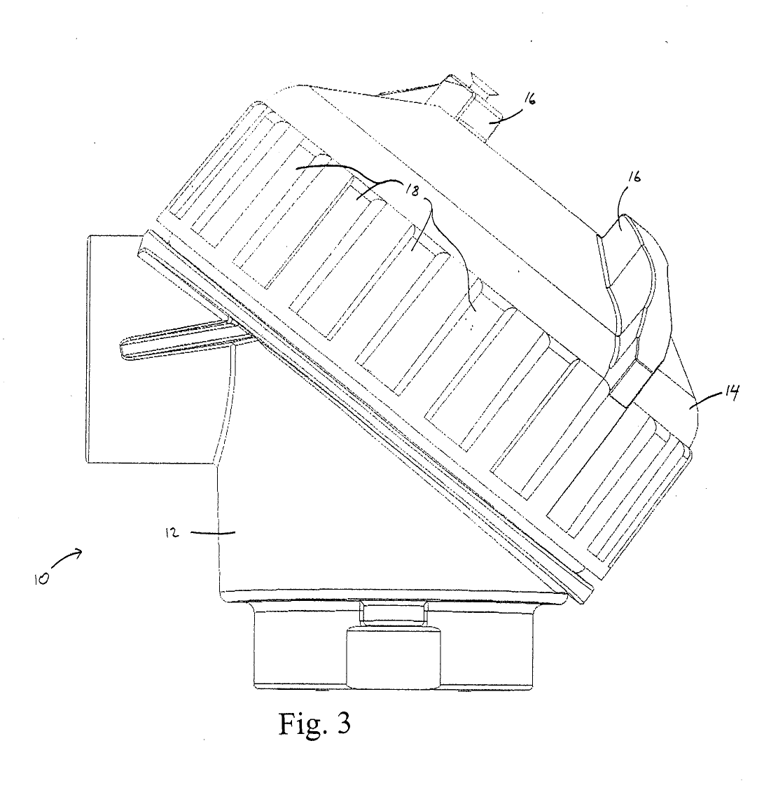

Referring to the drawings, a terminal connector head 10 formed in accordance with an embodiment of the present invention is shown. In the embodiment shown in FIGS. 1-3, terminal connector head 10 has a housing 12 and a cover 14. Embodiments are contemplated in which housing 12 is molded as a one-piece unit from a suitable material, such as a thermoplastic or metal. Examples of thermoplastic include polypropylene and a crystalline thermoplastic photopolymer marketed under the trademark DELRIN available from E. I. DuPont DeNemours & Co. Examples of metals from which housing 12 could be formed include aluminum, cast iron and 316 stainless steel. One skilled in the art should appreciate that the material from which the terminal connector head is formed will depend on the operating environment in which the terminal connector head 10 will be used.

In the embodiment shown, wings 16 extend from cover 14 for the user to more easily rotate cover 14 with respect to housing 12. As shown, the peripheral edge of cover 14 includes ribs 18 to reduce a user's hand from slipping when opening/closing cover 14. One skilled in the art should appreciate that a knurled surface or other surface ornamental could be used to reduce slippage of a user's hand when over/closing the cover 14. A chain 20 extends between housing 12 and cover 14. In the example shown, chain 20 has a first end connected with a wing 16 on cover 14 and a second end connected to a post 22 on housing 12. In one embodiment, the threads of cover 14 are configured so the ends of chain 16 are proximate each other on housing 12 and cover 14 when cover 14 is fully seated on housing 12. Chain 16 ensures that the cover 14 is not separated from the housing 12 when cover 14 is unscrewed from housing 12.

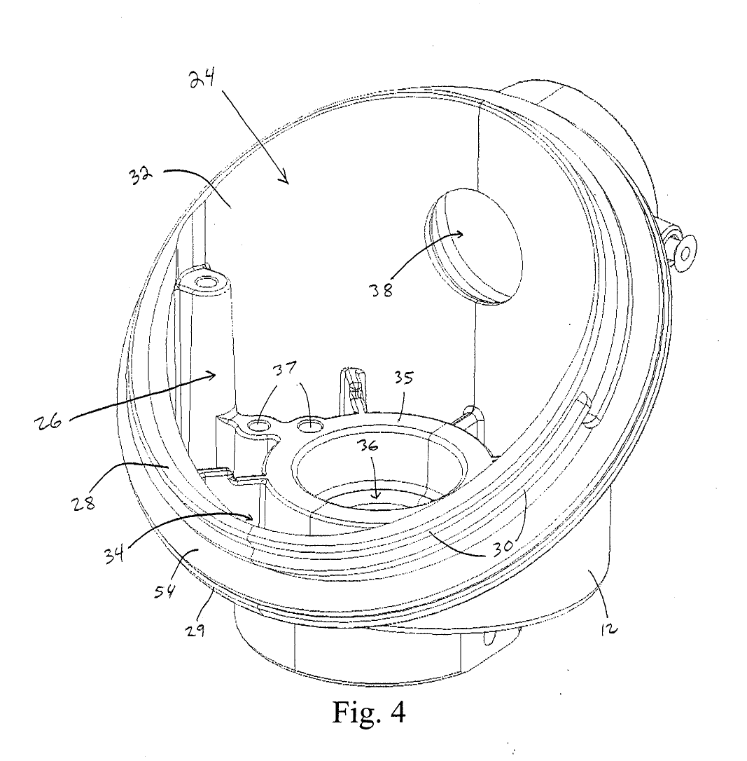

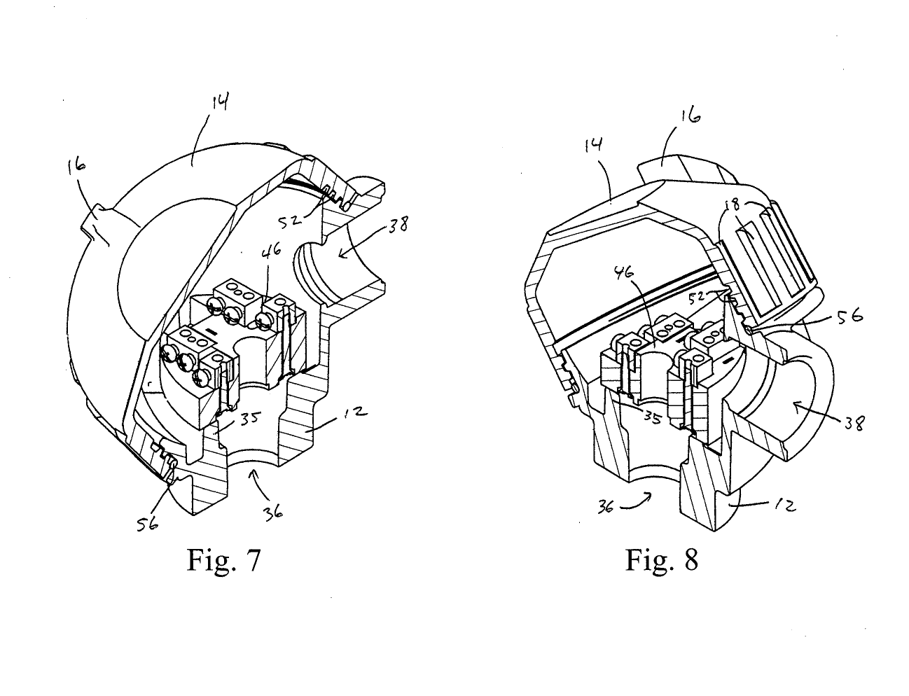

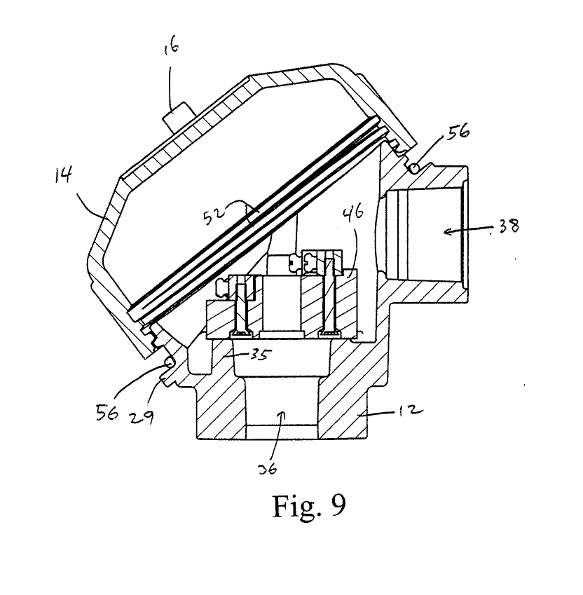

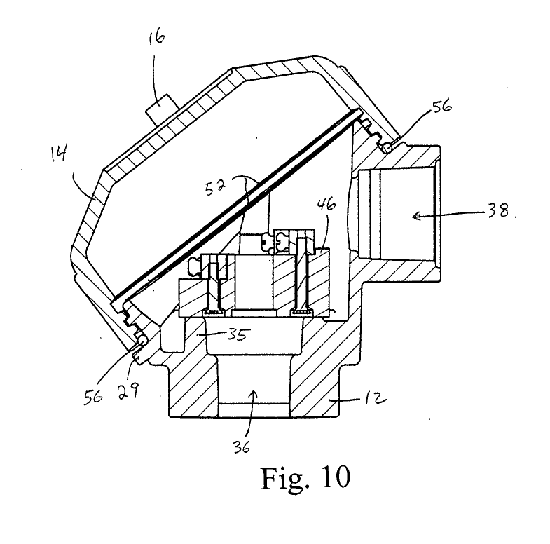

Referring to FIGS. 4-6, in which cover 14 has been removed, housing 12 is formed as a right cylinder having an elliptical cross-section and cut along a diagonal forming an annular opening 24 which exposes substantially the entire interior 26 of housing 12. Annular opening 24 is surrounded by an annular perimeter 28 which has threads 30 formed on an outer surface thereof. A flange 29 extends from annular perimeter 28 for receiving a seal, such as a gasket 54 (FIGS. 4-6) or o-ring 56 (FIGS. 7-10). Housing 12 has a curvelinear sidewall 32 and a base wall 34. An annular platform 35 extends from the base wall 34 so terminal connectors may be suspended above base wall 34 in a more convenient position for wiring and access. In the example shown, platform 35 includes threaded openings 37 to receive connecting elements, such as screws, for attaching a terminal block to platform 35.

A process opening 36 extends through base wall 34 into the interior 22 of housing 12. The inner wall of the process opening 36 is threaded. As is conventional, the protection tube or sheath of material surrounding a temperature sensing element is threaded at one end and is tightened into process opening 36 to secure a temperature sensor (not shown) to terminal connector head 10.

Curvelinear sidewall 32 of housing 12 has a threaded conduit opening 38 extending therethrough. A conduit is screwed into threaded conduit opening 38 in conventional fashion to mate terminal connector head 10 to a conduit (not shown).

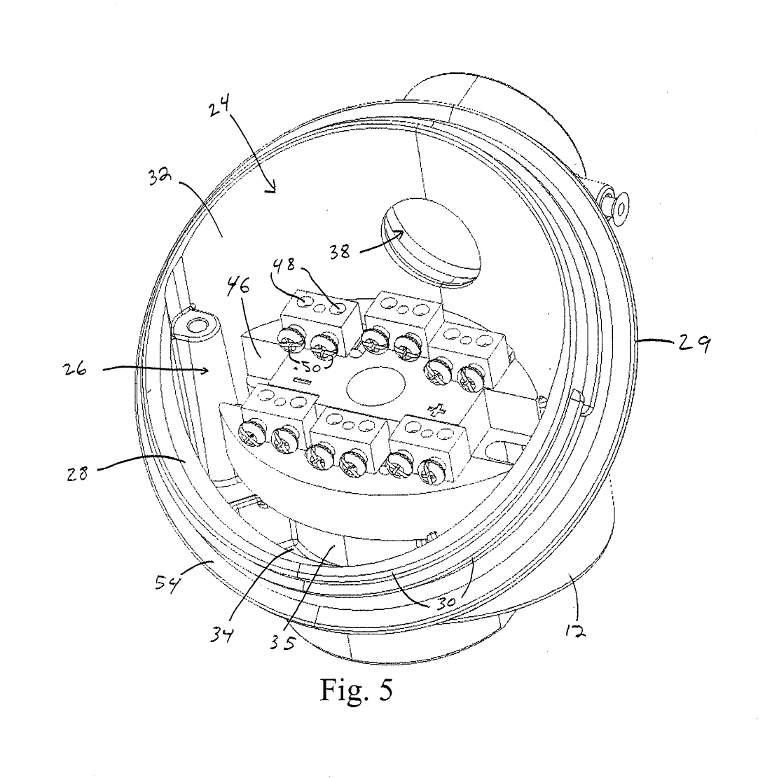

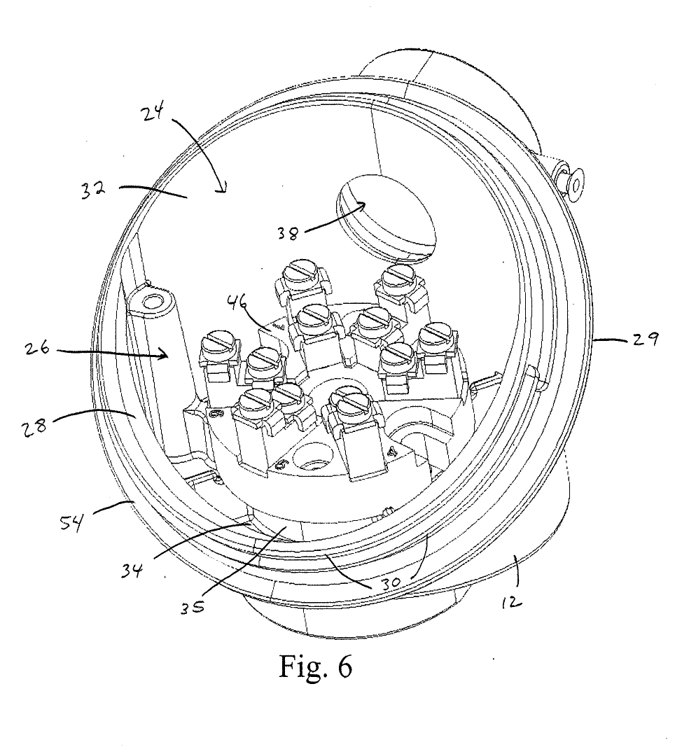

As can be seen in FIGS. 5 and 6, different types of terminal blocks 46 may be connected with platform 35. FIG. 5 shows an example in which the terminal block 46 is of the type sold by Pyromation, Inc. of Fort Wayne, Ind. The example in FIG. 6 shows a terminal block 46 of the DIN style. Terminal block 46 is typically formed from a material, such as ceramic, which has very high insulative and temperature resistance properties. A plurality of terminal block connecting elements 48 are mounted on terminal block 42. Terminal block connecting elements 48 are illustratively brass or nickel plated brass blocks having threaded holes formed therein which receive terminal screws 50.

As is conventional, the sensing element (not shown) has lead wires (not shown). These lead wires are passed into the interior 26 of housing 12 through process opening 36. Each lead wire is fastened to a connecting element 48 on the terminal block 46. An appropriate wire (not shown) for connecting each lead wire to a process instrument (not shown) is fastened to a corresponding connecting element 48 and passed out through conduit opening 38.

Referring to FIGS. 7-10, the cover 14 of terminal connector head 10 is illustratively a cap-like structure having an interior annular threaded perimeter 52. Cover 14 screws onto housing 12 to enclose the annular opening 24 of housing 12. The inner threaded perimeter 52 of cover 14 threadably mates with the threads 30 on the annular perimeter 28 surrounding annular opening 24 of housing 12. With the thread configuration in the embodiment shown, the cover 14 screws onto housing 12 with a single rotation. Unlike prior terminal heads that required several rotations to open/close cover 14, the single rotation to open/close cover 14 onto housing 12 provides quicker and easier access to interior 26.

Although the present disclosure has been described with reference to particular means, materials, and embodiments, from the foregoing description, one skilled in the art can easily ascertain the essential characteristics of the invention and various changes and modifications may be made to adapt the various uses and characteristics without departing from the spirit and scope of the invention.

What is claimed is:

1. A terminal connector head comprising:
a housing and a cover for removably mounting to the housing,
the housing having holes formed in an inner surface for alternatively receiving either a first type of terminal block or a second type of terminal block, and
wherein the first terminal block and the second terminal block are configured to be mounted in the housing by one or more attachment members which are received in a plurality of the holes.

2. The terminal connector head of claim 1, wherein the housing has an annular threaded perimeter and the cover has an annular threaded perimeter which threadably mates with the housing's annular threaded perimeter.

3. The terminal connector head of claim 2, wherein the annular threaded perimeter of the housing and the annular threaded perimeter of the cover are configured so the cover screws onto the housing with a rotation less than approximately 180 degrees.

4. The terminal connector head of claim 3, wherein the housing has a flange extending from the annular threaded perimeter that is configured to alternatively receive either a gasket or an o-ring.

5. The terminal connector head of claim 1, wherein the housing has a curvelinear sidewall and a base wall, a platform extending from the base wall for mounting one of the first terminal block or the second terminal block in a suspended position above the base wall.

6. The terminal connector head of claim 2, wherein the housing is formed from one or more of a thermoplastic material, aluminum, cast iron or stainless steel.

7. The terminal connector head of claim 1, wherein the housing has a threaded process opening and a threaded conduit opening.

8. A terminal connector head comprising:
a housing and a cover for removably mounting to the housing,
wherein the housing has an annular threaded perimeter and the cover has an annular threaded perimeter which threadably mates with the housing's annular threaded perimeter,
wherein the annular threaded perimeter of the housing and the annular threaded perimeter of the cover are configured for the cover to screw onto the housing with a rotation less than approximately 180 degrees, and
wherein the housing has a threaded process opening and a threaded conduit opening.

9. The terminal connector head of claim 8, wherein the housing has holes foamed in an inner surface for alternatively receiving either a first type of terminal block or a second type of terminal block.

10. The terminal connector head of claim 9, wherein the first terminal block and the second terminal block are configured to be mounted in the housing by one or more attachment members which are received in a plurality of the holes.

11. The terminal connector head of claim 10, wherein the housing has a curvelinear sidewall and a base wall, a platform extending from the base wall for mounting one of the first terminal block or the second terminal block in a suspended position above the base wall.

12. The terminal connector head of claim 8, wherein the housing has a flange extending from the annular threaded perimeter that is configured to alternatively receive either a gasket or an o-ring.

13. The terminal connector head of claim 8, wherein the housing is formed from one or more of a thermoplastic material, aluminum, cast iron or stainless steel.

14. A terminal connector head comprising:
a housing and a cover for removably mounting to the housing,
the housing having holes formed in an inner surface for alternatively receiving either a first type of terminal block or a second type of terminal block,
wherein the first terminal block and the second terminal block are configured to be mounted in the housing by one or more attachment members which are received in a plurality of the holes,
wherein the housing has an annular threaded perimeter and the cover has an annular threaded perimeter which threadably mates with the housing's annular threaded perimeter,
wherein the annular threaded perimeter of the housing and the annular threaded perimeter of the cover are configured so the cover screws onto the housing with a rotation less than approximately 180 degrees,
wherein the housing has a flange extending from the annular threaded perimeter that is configured to alternatively receive either a gasket or an o-ring,
wherein the housing has a curvelinear sidewall and a base wall, a platform extending from the base wall for mounting one of the first terminal block or the second terminal block in a suspended position above the base wall,
wherein the housing is formed from one or more of a thermoplastic material, aluminum, cast iron or stainless steel, and
wherein the housing has a threaded process opening and a threaded conduit opening.
